(19) United States
(12) Patent Application Publication
(10) Pub. No.: US 2023/0075852 A1
(43) Pub. Date: Mar. 9, 2023

(54) SEMICONDUCTOR STORAGE DEVICE AND MANUFACTURING METHOD THEREOF

(71) Applicant: Kioxia Corporation, Tokyo (JP)

(72) Inventor: Namiki YOSHIKAWA, Suzuka (JP)

(73) Assignee: Kioxia Corporation, Tokyo (JP)

(21) Appl. No.: 17/579,646

(22) Filed: Jan. 20, 2022

(30) Foreign Application Priority Data
Sep. 6, 2021 (JP) 2021-144550

(51) Int. Cl. H01L 27/11556; H01L 27/11582; H01L 27/11519; H01L 27/11565; H01L 27/11524; H01L 27/1157

(52) U.S. Cl. CPC H01L 27/11556; H01L 27/1157; H01L 27/11519; H01L 27/11524; H01L 27/11565; H01L 27/11582

(57) ABSTRACT

A semiconductor storage device according to the present embodiment includes a first stack including a plurality of first electrode films stacked in a first direction and electrically isolated from each other and a second stack provided above the first stack and including a plurality of second electrode films stacked in the first direction and electrically isolated from each other. An intermediate film is provided between the first stack and the second stack. A column portion includes a semiconductor layer provided to extend in the first direction in the first and second stacks and in the intermediate film and forms memory cells at an intersection of the semiconductor layer and at least one of the first electrode films and at an intersection of the semiconductor layer and at least one of the second electrode films. The intermediate film includes a silicon oxide film containing nitrogen.

### CROSS REFERENCE TO RELATED APPLICATIONS

This application is based upon and claims the benefit of priority from the prior Japanese Patent Application No. 2021-144550, filed on Sep. 6, 2021, the entire contents of which are incorporated herein by reference.

### FIELD

The embodiments of the present invention relate to a semiconductor storage device and a manufacturing method thereof.

### BACKGROUND

A semiconductor device such as a NAND flash memory may include a three-dimensional memory cell array having a plurality of memory cells arranged three-dimensionally. The number of stacked layers in the three-dimensional memory cell array is increasing every year, and the memory cell array may be formed as separate arrays including a lower array and an upper array.

In a case of forming the memory cell array as the lower array and the upper array, unevenness of a surface of the lower array is transferred to a multilayer film in the upper array when surface flatness of the lower array is poor. Such transfer of unevenness may cause a failure of a memory cell in the upper array.

Further, a channel semiconductor layer in a memory hole may become thin because of an uneven shape of an intermediate portion (a joint portion) between the lower array and the upper array, thus causing electrical disconnection.

### BRIEF DESCRIPTION OF THE DRAWINGS

FIG. 1A is a schematic perspective view of an example of a semiconductor storage device according to a first embodiment;

FIG. 1B is a schematic plan view of a stack in FIG. 1A;

FIG. 2A is a schematic cross-sectional view of an example of a memory cell having a three-dimensional configuration;

FIG. 2B is a schematic cross-sectional view of the example of the memory cell having a three-dimensional configuration;

FIG. 3 is a schematic plan view of an example of the semiconductor storage device according to the first embodiment;

FIG. 4 is a cross-sectional view illustrating an example of a more detailed configuration of the stack;

FIG. 5 is a cross-sectional view illustrating a configuration example of a joint portion between an upper array and a lower array;

FIG. 6 is a cross-sectional view illustrating an example of a manufacturing method of a semiconductor storage device according to the first embodiment;

FIG. 7 is a cross-sectional view illustrating an example of the manufacturing method of a semiconductor storage device following the method illustrated in FIG. 6;

FIG. 8 is a cross-sectional view illustrating an example of the manufacturing method of a semiconductor storage device following the method illustrated in FIG. 7;

FIG. 9 is a cross-sectional view illustrating an example of the manufacturing method of a semiconductor storage device following the method illustrated in FIG. 8;

FIG. 10 is a cross-sectional view illustrating an example of the manufacturing method of a semiconductor storage device following the method illustrated in FIG. 9;

FIG. 11 is a cross-sectional view illustrating an example of the manufacturing method of a semiconductor storage device following the method illustrated in FIG. 10;

FIG. 12 is a cross-sectional view illustrating an example of the manufacturing method of a semiconductor storage device following the method illustrated in FIG. 11;

FIG. 13 is a cross-sectional view illustrating an example of the manufacturing method of a semiconductor storage device following the method illustrated in FIG. 12;

FIG. 14 is a cross-sectional view illustrating an example of the manufacturing method of a semiconductor storage device following the method illustrated in FIG. 13;

FIG. 15 is a cross-sectional view illustrating an example of the manufacturing method of a semiconductor storage device following the method illustrated in FIG. 14;

FIG. 16 is a cross-sectional view of a region surrounded by a broken line frame in FIG. 13;

FIG. 17 is a cross-sectional view illustrating a configuration example of a joint portion according to a second embodiment; and

FIG. 18 is a cross-sectional view illustrating an example of a manufacturing method of a semiconductor storage device according to the second embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor storage device according to the present embodiment includes a first stack including a plurality of first electrode films stacked in a first direction and electrically isolated from each other and a second stack provided above the first stack and including a plurality of second electrode films stacked in the first direction and electrically isolated from each other. An intermediate film is provided between the first stack and the second stack. A column portion includes a semiconductor layer provided to extend in the first direction in the first and second stacks and in the intermediate film and forms memory cells at an intersection of the semiconductor layer and at least one of the first electrode films and at an intersection of the semiconductor layer and at least one of the second electrode films. The intermediate film includes a silicon oxide film containing nitrogen.

### First Embodiment

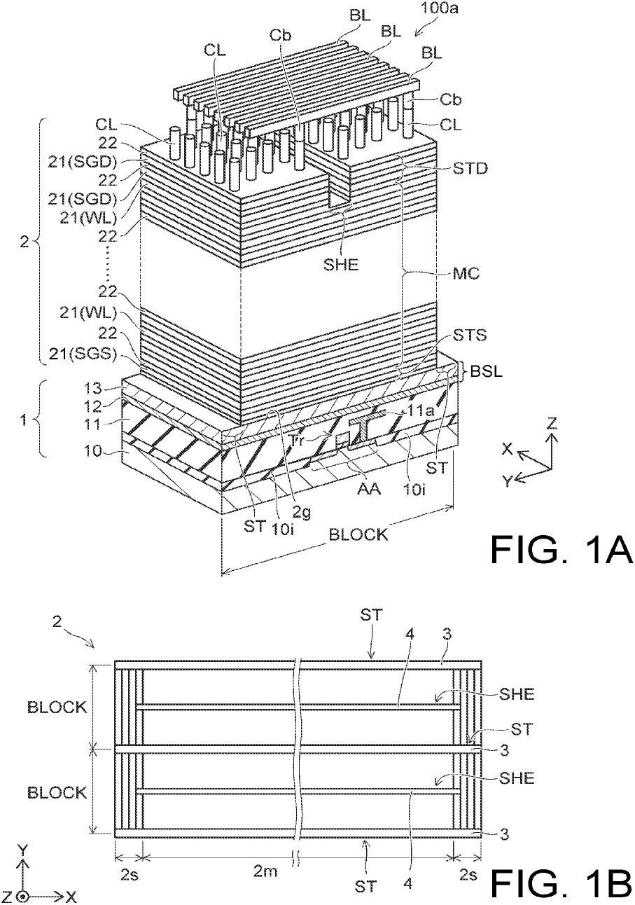

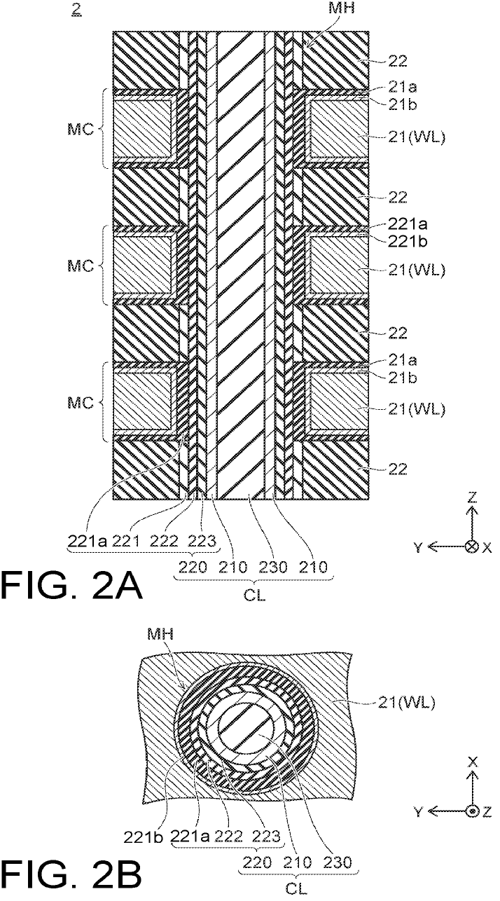

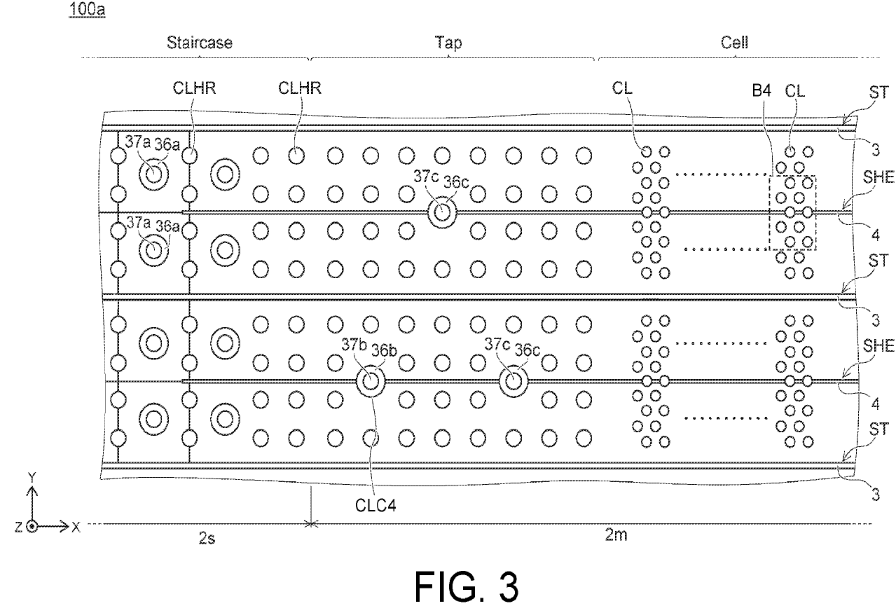

FIG. 1A is a schematic perspective view of an example of a semiconductor storage device 100a according to a first embodiment. FIG. 1B is a schematic plan view of a stack 2 in FIG. 1A. In the present specification, a stacking direction of the stack 2 is assumed as a Z-direction. One direction that crosses the Z-direction, for example, at right angles is assumed as a Y-direction. One direction that crosses the Z-direction and the Y-direction, for example, at right angles is assumed as an X-direction. FIGS. 2A and 2B are schematic cross-sectional views of an example of a memory cell having a three-dimensional configuration. FIG. 3 is a schematic plan view of an example of the semiconductor storage device according to the first embodiment.

As illustrated in FIG. 1A, the semiconductor storage device 100a according to the first embodiment is a non-volatile memory including memory cells having a three-dimensional configuration.

The semiconductor storage device 100a includes a base portion 1, the stack 2, a deep slit ST (a plate-shaped portion 3 in FIG. 1B), a shallow slit SHE (a plate-shaped portion 4 in FIG. 1B), and a plurality of column portions CL.

The base portion 1 includes a substrate 10, an interlayer dielectric film 11, a conductive layer 12, and a semiconductor portion 13. The interlayer dielectric film 11 is provided on the substrate 10. The conductive layer 12 is provided on the interlayer dielectric film 11. The semiconductor portion 13 is provided on the conductive layer 12.

The substrate 10 is a semiconductor substrate, for example, a silicon substrate. The conductivity type of silicon (Si) is, for example, a p-type. An element isolation region 10i, for example, is provided in a surface region of the substrate 10. The element isolation region 10i is an insulating region that contains silicon oxide (SiO₂), for example, and defines an active area AA in the surface region of the substrate 10. Source and drain regions of a transistor Tr are provided in the active area AA. The transistor Tr configures a peripheral circuit (a CMOS (Complementary Metal Oxide Semiconductor) circuit) of the non-volatile memory. The CMOS circuit is provided below a built-in source layer BSL and on the substrate 10. The interlayer dielectric film 11 contains, for example, silicon oxide and covers the transistor Tr. A wire 11a is provided in the interlayer dielectric film 11. A portion of the wire 11a is electrically connected to the transistor Tr. The conductive layer 12 contains doped polysilicon or conductive metal such as tungsten (W). The semiconductor portion 13 contains silicon, for example. The conductivity type of silicon is an n-type, for example. The semiconductor portion 13 may be formed by a plurality of layers, and a portion thereof may contain undoped silicon. Further, either the conductive layer 12 or the semiconductor portion 13 may be omitted.

The conductive layer 12 and the semiconductor portion 13 serve as a common source line of a memory cell array (2m in FIG. 1B). The conductive layer 12 and the semiconductor portion 13 are electrically connected to each other as one layer and are also collectively referred to as “built-in source layer BSL”.

The stack 2 is provided above the substrate 10 and is located in the Z-direction with respect to the conductive layer 12 and the semiconductor portion 13 (the built-in source layer BSL). The stack 2 is configured by a plurality of electrode films 21 and a plurality of insulation films 22 alternately stacked in the Z-direction. The electrode films 21 contain conductive metal such as tungsten, for example. The insulation films 22 contain silicon oxide, for example. The insulation films 22 insulate the electrode films 21 from each other. The stacked number of each of the electrode films 21 and the insulation films 22 may be any number. The insulation film 22 may be an air gap, for example. An insulation film 2g, for example, is provided between the stack 2 and the semiconductor portion 13. The insulation film 2g contains silicon oxide, for example. The insulation film 2g may contain a high dielectric material having a higher relative dielectric constant than silicon oxide. The high dielectric material may be metal oxide, for example.

The electrode films 21 include at least one source-side selection gate SGS, a plurality of word lines WL, and at least one drain-side selection gate SGD. The source-side selection gate SGS is a gate electrode of a source-side selection transistor STS. The word lines WL serve as gate electrodes of memory cells MC. The drain-side selection gate SGD is a gate electrode of a drain-side selection transistor STD. The source-side selection gate SGS is provided in a lower region of the stack 2. The drain-side selection gate SGD is provided in an upper region of the stack 2. The lower region is a region of the stack 2 closer to the base portion 1, and the upper region is a region of the stack 2 farther from the base portion 1. The word lines WL are provided between the source-side selection gate SGS and the drain-side selection gate SGD.

The thickness in the Z-direction of one of the insulation films 22 which insulates the source-side selection gate SGS and the word line WL from each other may be larger than, for example, the thickness in the Z-direction of the insulation film 22 that insulates the word lines WL from each other. Further, a cover insulation film (not illustrated) may be provided on the uppermost insulation film 22 that is the farthest from the base portion 1. The cover insulation film contains silicon oxide, for example.

The semiconductor storage device 100a includes the plural memory cells MC connected in series between the source-side selection transistor STS and the drain-side selection transistor STD. The configuration in which the source-side selection transistor STS, the memory cells MC, and the drain-side selection transistor STD are connected in series is called “memory string” or “NAND string”. One memory string is provided to correspond to each column portion CL and is connected to bit lines BL, for example, via contacts Cb. The bit lines BL are provided above the stack 2 and extend in the Y-direction.

The deep slits ST and the shallow slits SHE are provided in the stack 2. The deep slits ST extend in the X-direction and are provided in the stack 2 to penetrate through the stack 2 from the top end of the stack 2 to the base portion 1. The plate-shaped portion 3 is a wire provided in the deep slit ST. The plate-shaped portion 3 is formed by a conductive film that is electrically insulated from the stack 2 by an insulation film (not illustrated) provided on an inner wall of the deep slit ST, is embedded in the deep slit ST, and is electrically connected to the built-in source layer BSL. The plate-shaped portion 3 may be filled with an insulation material such as silicon oxide. Meanwhile, the shallow slits SHE extend in the X-direction and are provided from the top end of the stack 2 to the middle of the stack 2. The shallow slits SHE penetrate through the upper region of the stack 2 in which the drain-side selection gate SGD is provided. The plate-shaped portion 4, for example, is provided in the shallow slit SHE (FIG. 1B). The plate-shaped portion 4 is made of silicon oxide, for example.

As illustrated in FIG. 1B, the stack 2 includes staircase regions 2s and the memory cell array 2m. The staircase region 2s is provided at an edge of the stack 2. The memory cell array 2m is sandwiched between the staircase regions 2s or is surrounded by the staircase region 2s. The deep slit ST is provided from the staircase region 2s at one end of the stack 2 to the staircase region 2s at the other end of the stack 2 through the memory cell array 2m. The shallow slit SHE is provided at least in the memory cell array 2m.

As illustrated in FIG. 3, the memory cell array 2m includes a cell region (Cell) and a tap region (Tap) arranged in the X-direction. The staircase region 2s includes a staircase region (Staircase) at one end in the X-direction. The tap region is provided, for example, between the cell region and the staircase region. The tap region may be provided between the cell regions, although not illustrated in FIG. 3. The staircase region is a region where a plurality of wires 37a are provided. The tap region is a region where wires 37b and 37c are provided. The wires 37a to 37c extend in the Z-direction, for example. Each of the wires 37a is electrically connected to the electrode film 21, for example. The wire 37b is electrically connected to the built-in source layer BSL, for example. The wire 37c is electrically connected to the wire 11a, for example.

A portion of the stack 2 sandwiched between the two plate-shaped portions 3 illustrated in FIG. 1B is called “block (BLOCK)”. The block is the minimum unit for erasing data, for example. The plate-shaped portion 4 is provided in the block. The stack 2 between the plate-shaped portion 3 and the plate-shaped portion 4 is called “finger”. The drain-side selection gate SGD is divided for each finger. Therefore, in data writing and data reading, it is possible to place one finger in a block in a selected state by the drain-side selection gate SGD.

As illustrated in FIG. 2A, each of the column portions CL is provided in a memory hole MH formed in the stack 2. Each column portion CL penetrates through the stack 2 from the top end of the stack 2 in the Z-direction and is provided in the stack 2 and in the built-in source layer BSL. Each of the column portions CL includes a semiconductor body 210, a memory film 220, and a core layer 230. The column portion CL includes the core layer 230 provided at its center, the semiconductor body 210 provided around the core layer 230, and the memory film 220 provided around the semiconductor body 210. The semiconductor body 210 is electrically connected to the built-in source layer BSL. The memory film 220 as a charge storage member has a charge trapping portion between the semiconductor body 210 and the electrode film 21. The column portions CL selected one by one from the respective fingers are connected to one bit line BL in common via the contacts Cb. Each of the column portions CL is provided in the cell region (Cell), for example (FIG. 3). In each column portion CL, the memory cell MC is formed at each of intersections of the semiconductor body 210 extending in the Z-direction and the word lines WL other than the drain-side selection gate SGD and the source-side selection gate SGS among the electrode films 21 in the stack 2. The drain-side selection transistor STD and the source-side selection transistor STS are formed at intersections of the semiconductor body 210 and the drain-side selection gate SGD and the source-side selection gate SGS, respectively.

The shape of the memory hole MH in an X-Y plane is, for example, circular or elliptical, as illustrated in FIG. 2B. A block insulation film 221a that configures a portion of the memory film 220 may be provided between the electrode film 21 and the insulation film 22. The block insulation film 221a is, for example, a silicon oxide film or a metal oxide film. One example of the metal oxide is aluminum oxide. A barrier film 221b may be provided between the electrode film 21 and the insulation film 22 and between the electrode film 21 and the memory film 220. In a case where the electrode film 21 is made of tungsten, for example, titanium nitride, for example, is selected as the barrier film 221b. The block insulation film 221a prevents back tunneling of electric charges from the electrode film 21 toward the memory film 220. The barrier film 221b improves adhesion between the electrode film 21 and the block insulation film 221a.

The shape of the semiconductor body 210 is tubular with a bottom, for example. The semiconductor body 210 contains silicon, for example. Silicon contained here is polysilicon obtained by crystallizing amorphous silicon, for example. The semiconductor body 210 is made of, for example, undoped silicon. The semiconductor body 210 may be made of p-type silicon. The semiconductor body 210 serves as a channel of each of the drain-side selection transistor STD, the memory cell MC, and the source-side selection transistor STS.

A portion of the memory film 220 other than the block insulation film 221a is provided between the inner wall of the memory hole MH and the semiconductor body 210. The shape of the memory film 220 is tubular, for example. The memory film 220 is removed from the surrounding region of the semiconductor body 210 in a portion where the semiconductor body 210 is connected to the semiconductor portion 13 of the built-in source layer BSL. The memory cells MC each include a storage region between the semiconductor body 210 and the electrode film 21 serving as the word line WL and are stacked in the Z-direction. The memory film 220 includes, for example, a cover insulation film 221, a charge storage film 222, and a tunnel insulation film 223. The semiconductor body 210, the charge storage film 222, and the tunnel insulation film 223 extend in the Z-direction.

The cover insulation film 221 is provided between the insulation film 22 and the charge storage film 222. The cover insulation film 221 contains silicon oxide, for example. The cover insulation film 221 protects the charge storage film 222 from being etched when a sacrifice film (not illustrated) is replaced with the electrode film 21 (in a replacement process). The cover insulation film 221 may be removed from between the electrode film 21 and the memory film 220 in the replacement process. In this case, the block insulation film 221a, for example, is provided between the electrode film 21 and the charge storage film 222, as illustrated in FIGS. 2A and 2B. The cover insulation film 221 may not be included in a case where the replacement process is not used for forming the electrode film 21.

The charge storage film 222 is provided between the block insulation film 221a and the cover insulation film 221, and the tunnel insulation film 223. The charge storage film 222 contains, for example, silicon nitride and includes trap sites that trap therein electric charges. A portion of the charge storage film 222 which is sandwiched between the electrode film 21 serving as the word line WL and the semiconductor body 210 configures the storage region of the memory cell MC as a charge trapping portion. A threshold voltage of the memory cell MC is changed depending on whether electric charges are present in the charge trapping portion or in accordance with the amount of electric charges trapped in the charge trapping portion. Accordingly, the memory cell MC retains information.

The tunnel insulation film 223 is provided between the semiconductor body 210 and the charge storage film 222. The tunnel insulation film 223 contains silicon oxide, or silicon oxide and silicon nitride, for example. The tunnel insulation film 223 is a potential barrier between the semiconductor body 210 and the charge storage film 222. For example, when electrons are injected from the semiconductor body 210 to the charge trapping portion (in a write operation) and when holes are injected from the semiconductor body 210 to the charge trapping portion (in an erase operation), the electrons and the holes each pass (tunnel) through the potential barrier formed by the tunnel insulation film 223.

The core layer 230 is embedded in a space within the tubular semiconductor body 210. The shape of the core layer 230 is columnar, for example. The core layer 230 contains silicon oxide, for example, and is insulative.

Each of column portions CLHR in FIG. 3 is provided in a hole formed in the stack 2. The hole penetrates through the stack 2 from the top end of the stack 2 in the Z-direction and is provided in the stack 2 and in the built-in source layer BSL. Each of the column portion CLHR contains at least an insulator. The insulator is silicon oxide, for example. Each of the column portions CLHR may have the same configuration as the column portion CL. Each of the column portions CLHR is provided in the staircase region (Staircase) and the tap region (Tap), for example. The column portions CLHR serve as support members for maintaining gaps formed in the staircase region and the tap region when a sacrifice film (not illustrated) is replaced with the electrode film 21 (in a replacement process). A plurality of column portions CLC4 are provided in the tap region (Tap) of the stack 2. Each column portion CLC4 includes the wire 37b or 37c. The wire 37b is electrically insulated from the stack 2 by an insulator 36b. The wire 37b is electrically connected to the built-in source layer BSL. The wire 37c is electrically insulated from the stack 2 by an insulator 36c. The wire 37c is electrically connected to any of the wires 11a. The staircase region (Staircase) further includes the wire 37a serving as a contact with the electrode film 21 in the stack 2 and an insulator 36a provided around the wire 37a.

The column portions CL, that is, the memory holes MH are arranged in hexagonal close packing between two of the deep slits ST adjacent to each other in the Y-direction in a planar layout. The shallow slits SHE are provided to overlap some of the column portions CL, as illustrated in a frame B4 in FIG. 3. No memory cell is formed in the column portion CL under the shallow slit SHE.

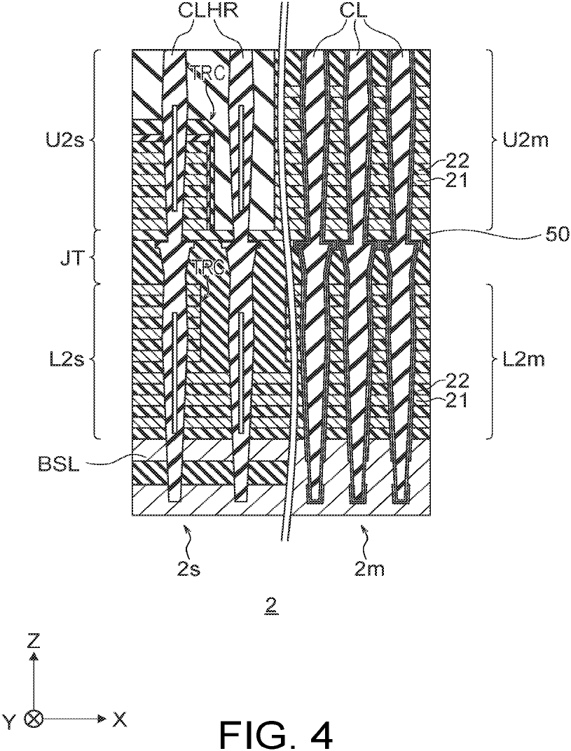

This three-dimensional memory cell array 2m may be formed by a plurality of separate steps, as the number of stacked layers increases. This is because it becomes more difficult to form the memory hole MH in a desired shape, as a stack in the memory cell array 2m becomes thicker. For example, the memory cell array 2m may be formed as two separate stacks including a lower array L2m and an upper array U2m, as illustrated in FIG. 4.

FIG. 4 is a cross-sectional view illustrating an example of a more detailed configuration of the stack 2. The configurations of the memory cell array 2m and the staircase region 2s are illustrated in parallel in FIG. 4.

The memory cell array 2m includes the lower array L2m and the upper array U2m. The staircase region includes a lower array L2s and an upper array U2s.

The lower arrays L2m and L2s are provided on the built-in source layer BSL. The upper arrays U2m and U2s are provided above the lower arrays L2m and L2s. The lower arrays L2m and L2s and the upper arrays U2m and U2s each include the electrode films 21 and the insulation films 22 alternately stacked in the Z-direction. The electrode films 21 adjacent to each other in the Z-direction are electrically isolated from each other by the insulation film 22. The insulation film 22 is provided between the electrode films 21 adjacent to each other in the Z-direction to electrically isolate these electrode films 21 from each other. A joint portion JT is provided between the lower arrays L2m and L2s and the upper arrays U2m and U2s. The configuration of the joint portion JT will be described later.

The column portions CL are provided in the upper array U2m and the lower array L2m of the memory cell array 2m to extend in the Z-direction. Each column portion CL penetrates through the upper array U2m and the lower array L2m and reaches the built-in source layer BSL. The column portion CL has the configuration described with reference to FIGS. 2A and 2B.

The column portions CLHR are provided in the upper array U2s and the lower array L2s of the staircase region 2s to extend in the Z-direction. Each column portion CLHR penetrates through the upper array U2s and the lower array L2s and reaches the built-in source layer BSL. The column portion CLHR is formed by a silicon oxide film as described with reference to FIG. 3. In addition, a step TRC is formed in the staircase region 2s so as to connect the wire (the contact) 37a to the electrode film 21 from the Z-direction.

An intermediate film 50 is provided between the upper arrays U2m and U2s and the lower arrays L2m and L2s. A silicon oxide film containing nitrogen, for example, is used as the intermediate film 50. The nitrogen concentration of the intermediate film 50 is higher than the nitrogen concentration of the insulation film 22. By providing this intermediate film 50 above the lower arrays L2m and L2s, it is possible to maintain surface flatness of the lower arrays L2m and L2s in the course of manufacturing. Therefore, it is possible to improve flatness of the upper arrays U2m and U2s formed above the lower arrays L2m and L2s. This improvement will be described later.

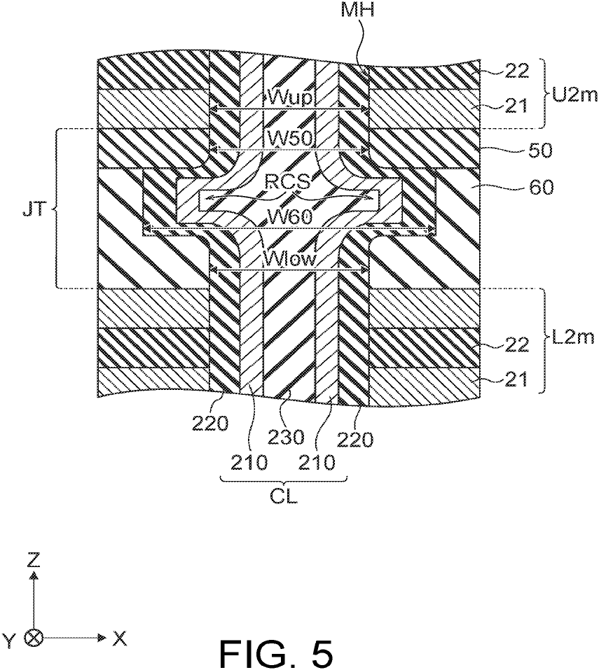

FIG. 5 is a cross-sectional view illustrating a configuration example of the joint portion JT between the upper array U2m and the lower array L2m. The joint portion JT between the upper array U2s and the lower array L2s also has a similar configuration.

An insulation film 60 and the intermediate film 50 are provided in the joint portion JT between the upper array U2m and the lower array L2m. The insulation film 60 is provided between the intermediate film 50 and the lower array L2m. The insulation film 60 includes, for example, a silicon oxide film. The insulation film 60 is thicker than the insulation film 22. The intermediate film 50 is provided between the insulation film 60 and the upper array U2m. The intermediate film 50 includes, for example, a silicon oxide film containing nitrogen. The nitrogen concentration of the intermediate film 50 is higher than the nitrogen concentration of the insulation film 60. The intermediate film 50 is thus higher in the nitrogen concentration than the insulation films 22 and 60.

An upper portion of the insulation film 60 (a portion closer to the upper array U2m in the Z-direction) is farther away from an axis of the column portion CL than the upper array U2m and the lower array L2m in a direction parallel to an X-Y plane. Therefore, the upper portion of the insulation film 60 is recessed in the X-Y plane direction relative to the upper array U2m and the lower array L2m to form a recess RCS in the joint portion JT. The memory film 220 and the semiconductor body 210 are embedded in the recess RCS. That is, a width W60 of the column portion CL in the upper portion of the insulation film 60 is larger than a width Wup of the column portion CL in the upper array U2m and a width Wlow of the column portion CL in the lower array L2m.

Further, the intermediate film 50 protrudes more than the upper portion of the insulation film 60 toward the column portion CL in the X-Y plane direction and eases the depth in the X-Y plane direction of the recess RCS at the position of the intermediate film 50. Therefore, the insulation film 60 is recessed in the X-Y plane direction relative to the intermediate film 50 in the recess RCS. That is, the width W60 of the column portion CL in the upper portion of the insulation film 60 is larger than a width W50 of the column portion CL in the intermediate film 50.

It suffices that a side surface of the intermediate film 50 on the column portion CL side is substantially flush with a side surface of each of the electrode film 21 and the insulation film 22 on the column portion CL side. However, a lower end of the intermediate film 50 on the column portion CL side is rounded by etching for residue removal described later. Therefore, it is possible to form the semiconductor body 210 on the inner wall of the memory hole MH in the joint portion JT with satisfactory coverage, so that it is possible to prevent the semiconductor body 210 from becoming thin or being cut in the joint portion JT.

In a case where the intermediate film 50 is not provided, a lower end of a sacrifice film as a lowermost film of the upper array U2m is not rounded but has a sharp corner in the process of manufacturing before a replacement process described later. This is because the sacrifice film (a silicon nitride film) is hardly etched in etching for removal of the residue (for example, an oxide) in the memory hole MH. In this case, the width of the column portion CL steeply changes from the width Wup in the upper array U2m to the width W60 in the insulation film 60 in the joint portion JT. Therefore, the memory film 220 and the semiconductor body 210 are largely bent from the Z-direction to the X-Y plane direction at the boundary between the upper array U2m and the insulation film 60. As a result, the semiconductor body 210 may become thin and be cut around the boundary between the upper array U2m and the insulation film 60. This cutting is more likely to occur, as a semiconductor device becomes more integrated and the semiconductor body 210 becomes thinner.

Meanwhile, according to the present embodiment, the intermediate film 50 is provided in the joint portion JT, and the lower end of the intermediate portion 50 on the column portion CL side is rounded. This configuration eases the change of the width of the column portion CL from the width Wup in the upper array U2m or the width W50 in the intermediate film 50 to the width W60 in the insulation film 60. Accordingly, the memory film 220 and the semiconductor body 210 are gently curved from the Z-direction to the X-Y plane direction at the boundary between the upper array U2m and the insulation film 60.

As described above, by providing the intermediate film 50, the coverage of the semiconductor body 210 is improved, and the thickness of the semiconductor body 210 can be made close to a uniform thickness also in the joint portion JT, so that the semiconductor body 210 can be prevented from being cut. As a result, it is possible to prevent a failure of a memory cell caused by cutting of the semiconductor body 210.

Next, a manufacturing method of the semiconductor storage device 100a according to the present embodiment is described.

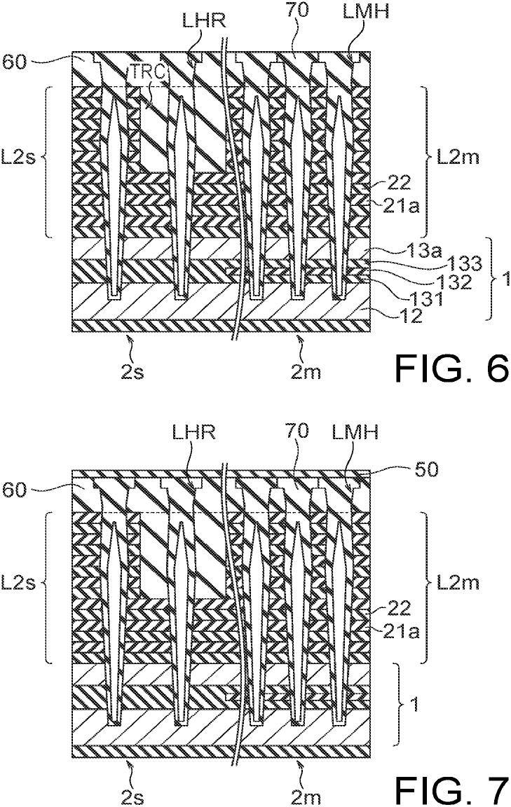

FIGS. 6 to 15 are cross-sectional views illustrating an example of a manufacturing method of the semiconductor storage device 100a according to the first embodiment.

First, the base portion 1 is formed. At this step, the base portion 1 includes a stacked structure of the conductive layer 12, an insulation film 131, a sacrifice film 132, an insulation film 133, and a semiconductor portion 13a. A conductive material such as doped polysilicon or metal is used for the conductive layer 12. An insulating material such as silicon oxide is used for the insulation films 131 and 133. A silicon nitride film, for example, is used as the sacrifice film 132. A conductive material such as doped polysilicon is used for the semiconductor portion 13a. The insulation film 131, the sacrifice film 132, and the insulation film 133 will be replaced with a conductor in a later process. This conductor forms the built-in source layer BSL together with the conductive layer 12 and the semiconductor portion 13a.

Next, plural sacrifice films 21a and the plural insulation films 22 are alternately stacked in the Z- direction above the base portion 1. A stack of the sacrifice films 21a and the insulation films 22 is thus formed in regions of the lower arrays L2m and L2s. An insulating material, for example, silicon nitride is used for the sacrifice film 21a. An insulating material, for example, silicon oxide, is used for the insulation film 22. The sacrifice films 21a are stacked in the Z-direction and are isolated from each other by the insulation films 22. The sacrifice films 21a will be replaced with the electrode films 21 in a later process.

Next, the lower array L2s in the staircase region 2s is processed, whereby the step TRC is formed. Next, the insulation film 60 is formed on the step TRC and the stack by CVD (Chemical Vapor Deposition), for example. An insulating material such as silicon oxide formed by using TEOS (Tetra Ethoxy Silane) is used for the insulation film 60. Next, the surface of the insulation film 60 is flattened by, for example, CMP (Chemical Mechanical Polishing).

Lower holes LMH and LHR are then formed to penetrate through the stack in the Z-direction by RIE (Reactive Ion Etching), for example.

Next, a resist film (not illustrated) is filled in the lower holes LMH and LHR, and an upper portion thereof is removed. A side surface of an upper portion of the insulation film 60 is thus exposed. Subsequently, the side surface of the upper portion of the insulation film 60 is etched by using the resist film as mask. Accordingly, the diameter of an opening in the upper portion of the insulation film 60 is made larger than the diameter of the lower hole LMH or LHR in the lower portion of the insulation film 60 and the lower array L2m or L2s. That is, since the diameters of the lower holes LMH and LHR are increased in the upper portion of the insulation film 60, upper holes UMH and UHR can communicate with the lower holes LMH and LHR, respectively, even when the positions of the upper holes UMH and UHR are somewhat shifted from the lower holes LMH and LHR in a process of forming the upper holes UMH and UHR described later. Therefore, the positions of the upper holes UMH and UHR can be easily aligned with the lower holes LMH and LHR.

Next, the resist film in the lower holes LMH and LHR is removed, and thereafter a sacrifice film 70 is filled in the lower holes LMH and LHR temporarily. A material that can be selectively etched with respect to a silicon nitride film and a silicon oxide film, for example, carbon or amorphous silicon is used for the sacrifice film 70. The sacrifice film 70 will be replaced with the column portions CL and CLHR in a later process. Therefore, it suffices that the sacrifice film 70 closes the openings of the lower holes LMH and LHR. A void may be generated below the sacrifice film 70. Next, the surface of the insulation film 60 and the surface of the sacrifice film 70 are flattened by CMP, for example. Accordingly, the structure illustrated in FIG. 6 is obtained.

Next, the intermediate film 50 is formed above the stacks of the lower arrays L2m and L2s, as illustrated in FIG. 7. A silicon nitride film, for example, is formed as the intermediate film 50 at first.

In a case where a silicon oxide film is formed as the intermediate film 50 at first, the sacrifice film 70 (for example, made of carbon) may be oxidized and scraped in deposition of the intermediate film 50. In this case, the surface of the sacrifice film 70 is recessed in the Z-direction with respect to the surface of the insulation film 60, and the surface of the intermediate film 50 deposited on the films 70 and 60 also becomes uneven, so that flatness of the intermediate film 50 is deteriorated.

On the other hand, according to the present embodiment, a silicon nitride film is formed as the intermediate film 50 at first. Accordingly, oxidation of the sacrifice film 70 (for example, made of carbon) can be prevented in formation of the intermediate film 50. Therefore, the sacrifice film 70 is hardly depressed with respect to the surface of the insulation film 60, and surface flatness of the intermediate film 50 is maintained.

Next, the intermediate film 50 is oxidized. At this step, the intermediate film 50 is oxidized by, for example, ISSG (In-Situ Steam Generation) oxidation. ISSG oxidation is a technique of forming an oxide film by introducing hydrogen and oxygen directly into a chamber and causing generation of water vapor (H₂O) in the chamber. Accordingly, the intermediate film 50 is changed to a silicon oxide film containing nitrogen. Since the intermediate film 50 is a silicon oxide film obtained by oxidizing a silicon nitride film, its nitrogen concentration is higher than the nitrogen concentrations of the insulation films 22 and 60.

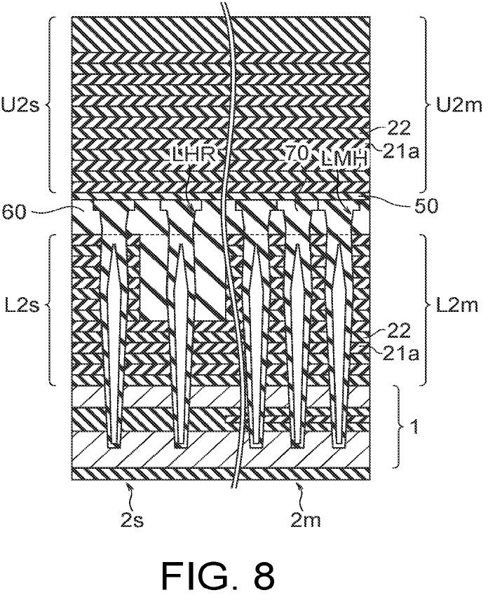

Next, the sacrifice films 21a and the insulation films 22 are alternately stacked in the Z-direction on the intermediate film 50, as illustrated in FIG. 8. Accordingly, a stack of the sacrifice films 21a and the insulation films 22 is formed in regions of the upper arrays U2m and U2s. An insulating material, for example, silicon nitride is used for the sacrifice film 21a. An insulating material, for example, silicon oxide, is used for the insulation film 22. The sacrifice films 21a are stacked in the Z-direction and are isolated from each other by the insulation films 22. The sacrifice films 21a will be replaced with the electrode films 21 in a later process. At this step, in a case where the lower holes LMH and LHR are filled with, in particular, carbon as the sacrifice film 70, it is possible to reduce the possibility that the stacks in the regions of the lower arrays L2m and L2s are warped because of, for example, a thermal history in formation of stacks of the upper arrays U2m and U2s.

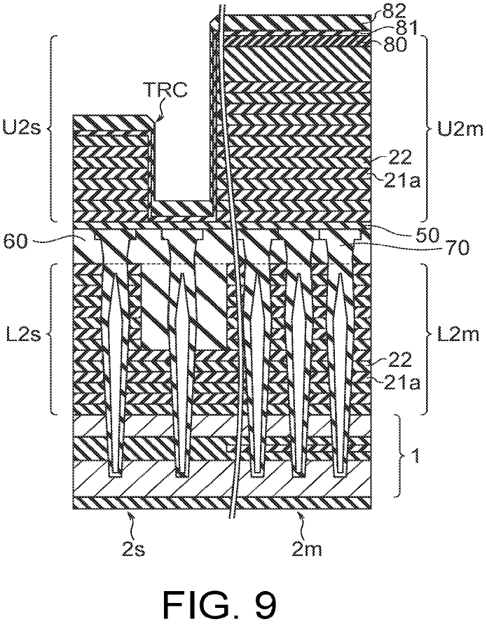

Next, the upper array U2s in the staircase region 2s is processed, whereby the step TRC is formed, as illustrated in FIG. 9. At this time, the intermediate film 50 serves as a stopper, so that the step TRC in the upper array U2s does not reach the insulation film 60 and the sacrifice film 70 in the lower hole LHR remains covered by the intermediate film 50. Accordingly, the sacrifice film 70 in the lower hole LHR can be protected so as not to be scraped, for example, in a process of removing a mask material used for processing the upper array U2s. In addition, a stopper film 80 is formed on the upper array U2m. For example, a silicon nitride film is used as the stopper film 80.

Next, insulation films 81 and 82 are formed on the stacks of the upper arrays U2s and U2m. A silicon oxide film, for example, is used as the insulation film 81. A silicon nitride film, for example, is used as the insulation film 82. Accordingly, the structure illustrated in FIG. 9 is obtained.

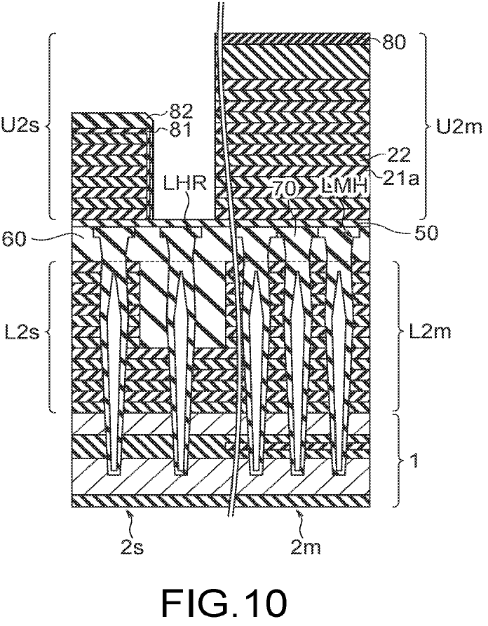

Next, the insulation films 82 and 81 in a region of the memory cell array 2m other than the staircase region 2s are etched back by lithography and etching, as illustrated in FIG. 10.

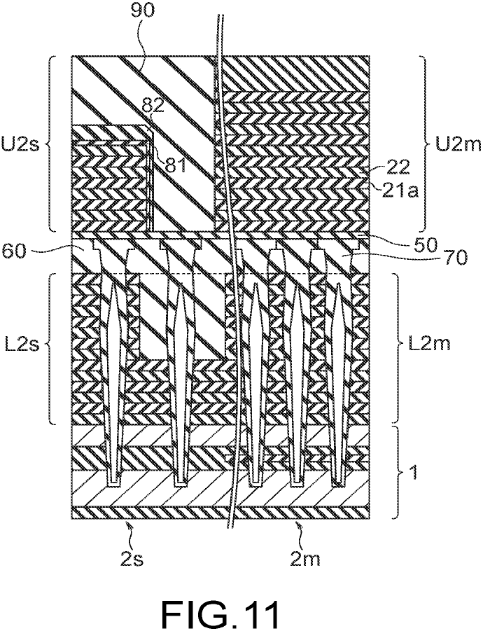

Next, an insulation film 90 is deposited on the upper arrays U2m and U2s and is flattened by CMP to the position of the stopper film 80, as illustrated in FIG. 11. The insulation film 90 is thus embedded in the staircase region 2s. A silicon oxide film, for example, is used as the insulation film 90. Thereafter, the stopper film 80 on the upper array U2m is removed.

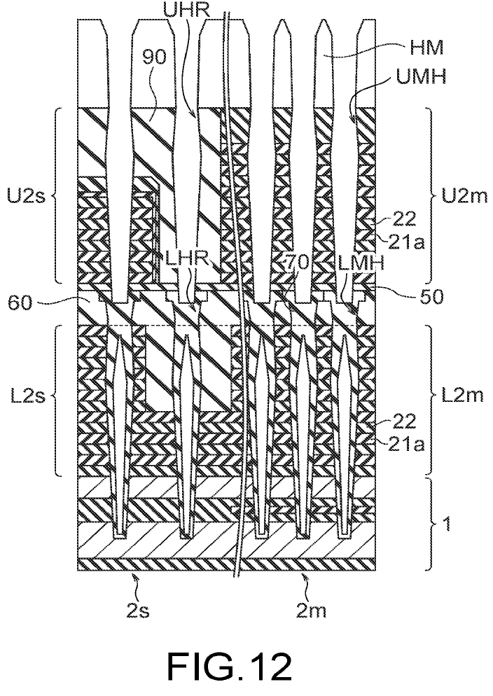

Next, a mask material HM is formed above the upper arrays U2m and U2s, as illustrated in FIG. 12. The mask material HM is processed into a pattern of the upper holes UMH and UHR by lithography and etching. Next, the stacks of the upper array U2m and U2s and the intermediate film 50 are processed by RIE using the mask material HM as mask. Accordingly, the upper holes UMH and UHR are formed to penetrate through the stacks of the upper arrays U2m and U2s and the intermediate film 50 in the Z-direction. The upper holes UMH and UHR are formed to correspond to the positions directly above the lower holes LMH and LHR, respectively. At this step, the opening in the upper portion of the insulation film 60 is widened to have a larger diameter than the lower holes LMH and LHR in the lower portion of the insulation film 60 and the lower arrays L2m and L2s. Therefore, the upper holes UMH and UHR can be easily aligned above the corresponding lower holes LMH and LHR, respectively. Accordingly, the upper holes UMH and UHR can easily communicate with the corresponding lower holes LMH and LHR, respectively.

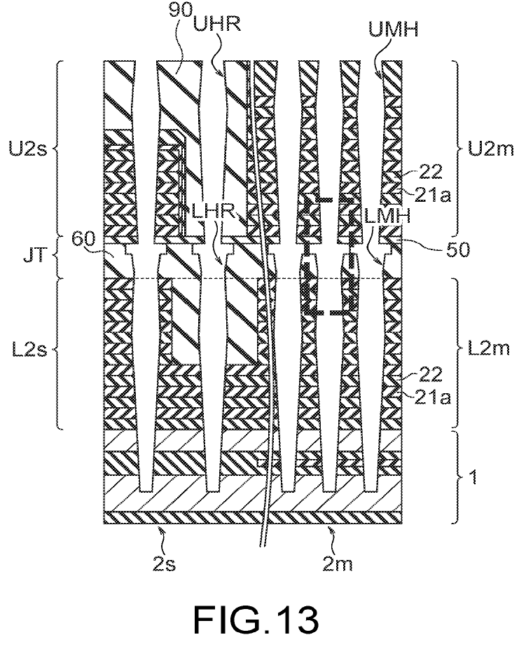

Next, the sacrifice film 70 in the lower holes LMH and LHR is removed via the upper holes UMH and UHR, as illustrated in FIG. 13. In a case where the sacrifice film 70 is made of carbon, for example, the sacrifice film 70 is oxidized and removed by using an asher. Accordingly, the sacrifice film 70 can be easily removed.

Next, the inner walls of the upper holes UMH and UHR and the lower holes LMH and LHR are etched by using, for example, hydrofluoric acid solution (BHF (Buffered Hydrogen Fluoride)). Accordingly, the residue in the upper holes UMH and UHR and the lower holes LMH and LHR is removed.

At this step, the intermediate film 50 and the insulation film 60 on the inner wall in the joint portion JT are slightly etched. According to the present embodiment, the intermediate film 50 is a silicon oxide film obtained by oxidizing a silicon nitride film by ISSG oxidation, and therefore has a higher nitrogen concentration than the insulation films 22 and 60. Therefore, an etching rate of the intermediate film 50 is higher than that of the sacrifice film 21a but is lower than those of the insulation films 22 and 60. Accordingly, the intermediate film 50 is slightly etched and rounded at a lower end of a side surface thereof exposed in the upper hole UMH. However, the intermediate film 50 does not become distant from the upper hole UMH in the X-Y plane direction largely. Further, an angular lower end of the sacrifice film 21a that is the lowermost film in the upper array U2m is not exposed by progress of etching in the Z-direction from the bottom surface of the intermediate film 50 exposed in a widened portion of the lower hole LMH.

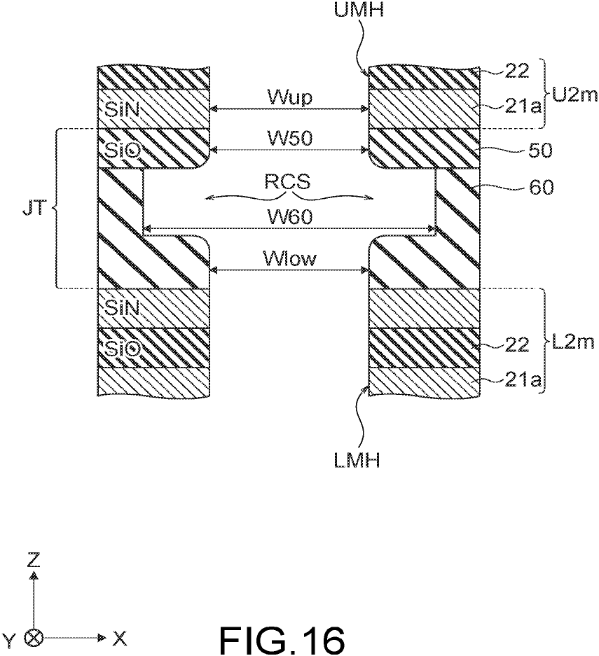

FIG. 16 is a cross-sectional view of a region surrounded by a broken line frame in FIG. 13. As illustrated in FIG. 16, the width W60 of the lower hole LMH in the upper portion of the insulation film 60 with the recess RCS formed therein is larger than the width Wlow of the lower hole LMH in the lower portion of the insulation film 60 and the width Wup of the upper hole UMH, and is increased in a direction away from the center of the upper hole UMH. Meanwhile, the intermediate film 50 protrudes more than the upper portion of the insulation film 60 toward the center of the upper hole UMH. Therefore, the width W50 of the upper hole UMH in the intermediate film 50 is smaller than the width W60 of the lower hole LMH in the upper portion of the insulation film 60, as illustrated in FIG. 16. Further, since the lower end of the intermediate film 50 is rounded, change of the depth in the X-Y plane direction of the recess RCS is eased. Therefore, it is possible to form the semiconductor body 210 on the inner wall of the memory hole MH in the joint portion JT with satisfactory coverage, so that it is possible to prevent the semiconductor body 210 from becoming thin or being cut in the joint portion JT. The inner wall of a hole formed by the lower hole LHR and the upper hole UHR in the staircase region 2s also has an identical shape.

In the present embodiment, as for the insulation film 22, the insulation film 60, and the intermediate film 50 that are formed by silicon oxide films, the insulation film 22, for example, may be formed by a silicon oxide film with a higher density than the insulation film 60 and the intermediate film 50. This configuration can make the etching rate of the insulation film 22 lower than those of the insulation film 60 and the intermediate film 50. In addition, the intermediate film 50 is formed by a silicon oxide film with a higher nitrogen concentration than the insulation film 60. Therefore, the etching rate of the intermediate film 50 can be made lower than that of the insulation film 60.

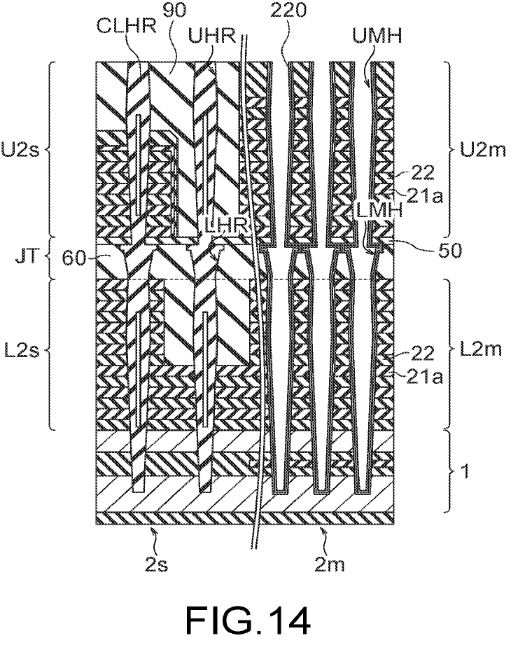

Next, an insulation film such as a silicon oxide film is embedded in the upper hole UHR and the lower hole LHR in the staircase region 2s to form the column portion CLHR, as illustrated in FIG. 14. The column portion CLHR serves as a support for the insulation films 22 when the sacrifice films 21a are replaced with the electrode films 21 later.

Further, the memory film 220 is formed on the inner walls of the lower hole LMH and the upper hole UMH in a region of the memory cell array 2m. For example, the cover insulation film 221, the charge storage film 222, and the tunnel insulation film 223 are formed on the inner walls of the lower hole LMH and the upper hole UMH in that order.

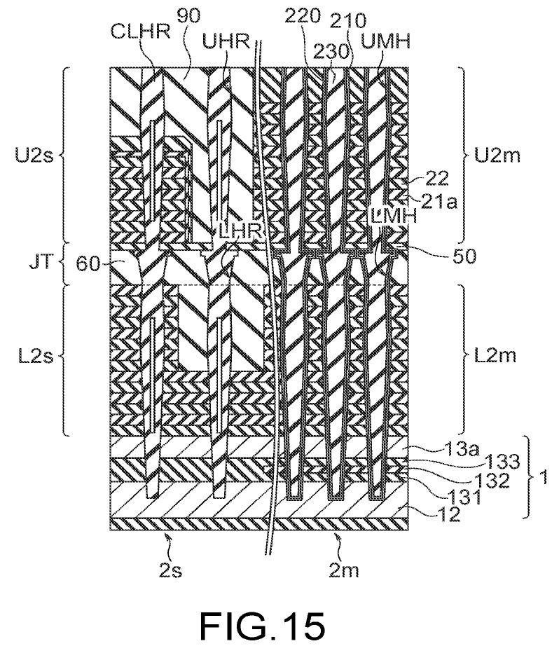

Next, the semiconductor body 210 is formed inside the memory film 220 in the upper hole UMH and the lower hole LMH in the region of the memory cell array 2m, as illustrated in FIG. 15.

At this step, the upper portion of the insulation film 60 is recessed in the X-Y plane direction relative to the upper arrays U2m and U2s and the lower arrays L2m and L2s, and the lower end of the intermediate film 50 is rounded. Therefore, bending of the semiconductor body 210 is eased at the boundary between the intermediate film 50 and the insulation film 60 (the boundary between the upper hole UMH and the lower hole LMH). Accordingly, satisfactory coverage of the semiconductor body 210 is obtained in the joint portion JT, so that it is possible to prevent the semiconductor body 210 from being cut.

Further, the core layer 230 is embedded inside the memory film 220 and the semiconductor body 210 in the upper hole UMH and the lower hole LMH in the region of the memory cell array 2m.

Thereafter, the slit ST (see FIGS. 1A and 1B) is formed. The insulation films 131 and 133 and the sacrifice film 132 in the region of the memory cell array 2m are replaced with a conductive material (for example, polysilicon) via the slit ST to form the built-in source layer BSL. Further, the sacrifice films 21a are removed via the slit ST. Spaces are thus formed between the insulation films 22 adjacent to each other in the Z-direction. A conductive material (for example, tungsten) is embedded in these spaces via the slit ST, whereby the electrode films 21 are formed between the insulation films 22. Accordingly, the stack 2 illustrated in FIG. 4 is formed.

Thereafter, contacts and bit lines (both not illustrated) are formed. Accordingly, the semiconductor storage device 100a according to the present embodiment is completed. The semiconductor storage device 100a may be formed by forming a CMOS circuit of the base portion 1 on another substrate and bonding the substrate with the stack 2 and the substrate with the CMOS circuit to each other.

According to the present embodiment, the intermediate film 50 is formed on the insulation film 60 and the sacrifice film 70 in the lower holes LMH and LHR. Since the intermediate film 50 is a silicon nitride film in an initial stage of formation, oxidation of the sacrifice film 70 (for example, made of carbon) can be prevented. Therefore, it is possible to maintain surface flatness of the intermediate film 50. By maintaining the surface flatness of the intermediate film 50 to be satisfactory, surface flatness of the upper arrays U2m and U2s formed thereon also becomes satisfactory.

Further, according to the present embodiment, the intermediate film 50 is provided between the insulation film 60 and the upper arrays U2m and U2s. A silicon oxide film with a higher nitrogen concentration than the insulation film 60 is used as the intermediate film 50. Therefore, the intermediate film 50 has a lower etching rate than the insulation film 60, and the lower end of the intermediate film 50 is rounded although the intermediate film 50 protrudes more than the upper portion of the insulation film 60 in the X-Y plane direction in the joint portion JT. This configuration eases the step at the boundary between the upper array U2m and the insulation film 60 and also eases bending of the semiconductor body 210 in the joint portion JT. As a result, satisfactory coverage of the semiconductor body 210 is obtained in the joint portion JT, so that the semiconductor body 210 can be prevented from being cut.

In the first embodiment described above, the intermediate film 50 is a silicon nitride film in an initial stage of formation and is then oxidized to become a silicon oxide film containing nitrogen. However, the intermediate film 50 may be a silicon oxide film formed by the ULT (Ultra Low Temperature) technique. In the ULT technique, a silicon oxide film is formed in a low temperature atmosphere, for example, at a room temperature by using aminosilane such as dialkyl aminosilane as the material. In this case, since formation can be performed in a low temperature atmosphere, the sacrifice film 70 (for example, made of carbon) is less likely to be oxidized in deposition of the silicon oxide film, so that surface flatness of the intermediate film 50 can be maintained. In addition, the silicon oxide film formed by this ULT technique has higher nitrogen concentration and carbon concentration than, for example, a silicon oxide film formed using TEOS because the former one uses aminosilane as the material. Therefore, the silicon oxide film formed by the ULT technique has a lower etching rate than the silicon oxide film formed using TEOS. Accordingly, identical effects to those in the embodiment described above can be obtained also in a case of using the silicon oxide film formed by the ULT technique as the intermediate film 50.

### Second Embodiment

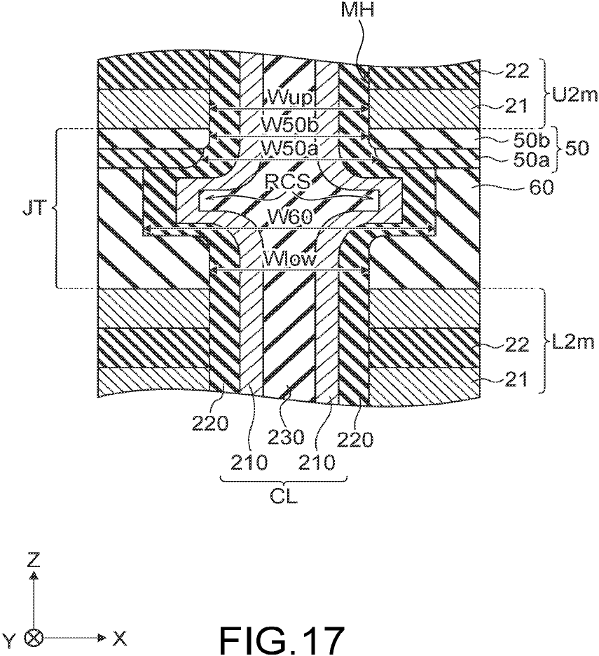

FIG. 17 is a cross-sectional view illustrating a configuration example of the joint portion JT according to a second embodiment. In the second embodiment, the intermediate film 50 includes a partial film 50a and a partial film 50b. The partial film 50a includes a silicon oxide film containing nitrogen, as with the intermediate film 50 according to the first embodiment.

For example, the partial film 50a is a silicon oxide film formed by the ULT technique using aminosilane such as dialkyl aminosilane. In this case, the partial film 50a is a silicon oxide film containing nitrogen and carbon. The nitrogen concentration and the carbon concentration of the partial film 50a are higher than the nitrogen concentration and the carbon concentration of the partial film 50b.

The partial film 50b is provided on the partial film 50a and is a silicon oxide film that is lower in the nitrogen concentration and/or the carbon concentration than the partial film 50a. It suffices that the partial film 50b is, for example, a silicon oxide film formed using TEOS, as with the insulation film 60. According to this technique, it is possible to form a silicon oxide film with higher productivity than the partial film 50a.

In this case, the partial film 50b has a higher etching rate than the partial film 50a, as with the insulation film 60. However, the partial film 50b is not provided when the lower array L2m is formed, and is only slightly etched at a lower end of a side surface exposed in the memory hole MH by hydrofluoric acid solution (BHF) when the memory hole MH is formed after the upper array U2m is stacked. Therefore, the partial film 50b is not depressed in a direction away from the column portion CL (the X-Y plane direction), unlike the upper portion of the insulation film 60. The partial film 50b is rounded at the lower end on the column portion CL side together with the partial film 50a. Therefore, the upper portion of the insulation film 60 is recessed in the X-Y plane direction relative to the upper array U2m and the lower array L2m to form a recess RCS in the joint portion JT. Meanwhile, the partial films 50a and 50b protrude more than the insulation film 60 toward the column portion CL in the X-Y plane direction between the insulation film 60 and the upper array U2m.

A width W50a of the memory hole MH (the column portion CL) in the partial film 50a is somewhat larger than the widths Wup and Wlow of the memory hole MH (the column portion CL) in the upper array U2m and the lower array L2m. In addition, a width W50b of the memory hole MH in the partial film 50b is approximately equal to or somewhat smaller than the width W50a.

According to the second embodiment, since the patrial film 50a of the intermediate film 50 is provided in the joint portion JT, lower ends of both the partial films 50a and 50b are rounded, so that bending of the inner wall of the memory hole MH from the Z-direction to the X-Y plane direction is eased at the boundary between the upper array U2m and the insulation film 60. Therefore, coverage of the semiconductor body 210 is improved, and it is possible to prevent the semiconductor body 210 from being cut also in the joint portion JT. Further, as compared with a case of using the partial film 50a alone, the intermediate film 50 including both the partial films 50a and 50b can enhance the effect of protecting the sacrifice film 70 in the lower hole LHR when the upper array U2s is processed.

As described above, by providing the intermediate film 50 including the partial film 50a and the partial film 50b, the coverage of the semiconductor body 210 is improved, and the thickness of the semiconductor body 210 can be made close to a uniform thickness also in the joint portion JT. As a result, the semiconductor body 210 is prevented from being cut, so that a failure of a memory cell caused by cutting of the semiconductor body 210 can be prevented.

Other configurations of the second embodiment are identical to corresponding configurations of the first embodiment. Therefore, the second embodiment can obtain effects identical to those of the first embodiment.

Next, a manufacturing method of the semiconductor storage device 100a according to the second embodiment is described.

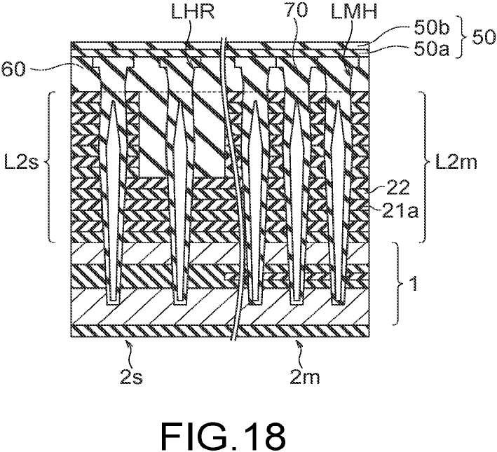

FIG. 18 is a cross-sectional view illustrating an example of a manufacturing method of the semiconductor storage device 100a according to the second embodiment.

After the processes described with reference to FIG. 6, the intermediate film 50 is formed above stacks of the lower arrays L2m and L2s, as illustrated in FIG. 18. The intermediate film 50 includes the partial films 50a and 50b.

The partial film 50a is a silicon oxide film formed by the ULT technique described above. The silicon oxide film formed by this ULT technique has higher nitrogen concentration and carbon concentration than, for example, a silicon oxide film formed using TEOS. In addition, according to the ULT technique, it is possible to form a silicon oxide film in a low temperature atmosphere at around room temperature, and the partial film 50a is less likely to oxidize the sacrifice film 70 (for example, made of carbon) as compared with a silicon oxide film formed using TEOS. Therefore, the sacrifice film 70 is not much depressed with respect to the surface of the insulation film 60, and surface flatness of the lower arrays L2m and L2s is easily maintained. Further, the recess RCS is formed in a side surface of the upper portion of the insulation film 60 in the lower holes LMH and LHR. With this configuration, the upper holes UMH and UHR can communicate with the lower holes LMH and LHR, respectively, even when the positions of the upper holes UMH and UHR are somewhat shifted from the lower holes LMH and LHR.

Next, the partial film 50b is formed on the partial film 50a. A silicon oxide film formed using TEOS, for example, is used as the partial film 50b. However, the partial film 50b hardly oxidizes the sacrifice film 70 because the partial film 50b is formed on the partial film 50a. The partial film 50b has lower nitrogen concentration and carbon concentration than the partial film 50a and has a higher etching rate than the partial film 50a.

Thereafter, the processes described with reference to FIGS. 8 to 15 are performed. In the process illustrated in FIG. 13, etching using hydrofluoric acid solution (BHF) is performed, whereby the inner wall of the memory hole MH in the joint portion JT has the shape as illustrated in FIG. 17. Thereafter, the identical processes to those in the first embodiment are performed, so that the semiconductor storage device 100a according to the second embodiment is completed.

According to the second embodiment, the intermediate film 50 is formed on the insulation film 60 and the sacrifice film 70 in the lower holes LMH and LHR. The intermediate film 50 includes a silicon oxide film formed by the ULT technique as the partial film 50a. The partial film 50a covers the insulation film 60 and the sacrifice film 70. With this configuration, surface flatness of the lower arrays L2m and L2s (the insulation film 60 and the sacrifice film 70) can be maintained, and surface flatness of the upper arrays U2m and U2s also becomes satisfactory.

Further, the upper portion of the insulation film 60 is recessed in the X-Y plane direction relative to the upper arrays U2m and U2s and the lower arrays L2m and L2s in the joint portion JT. Meanwhile, a silicon oxide film with higher nitrogen concentration and carbon concentration than the insulation film 60 and the partial film 50b is used as the partial film 50a. Therefore, the partial film 50a has a lower etching rate than the insulation film 60 and the partial film 50b, and protrudes more than the upper portion of the insulation film 60 in the X-Y plane direction in the joint portion JT. Although a silicon oxide film that is identical to the insulation film 60 is used as the partial film 50b, the partial film 50b is provided between the partial film 50a and the upper array U2m and is only slightly etched by hydrofluoric acid solution (BHF) when the memory hole MH is formed in the upper array U2m. Therefore, the partial film 50b is not depressed in a direction away from the column portion CL (the X-Y plane direction), unlike the upper portion of the insulation film 60. Meanwhile, the partial film 50b is rounded at its lower end on the column portion CL side together with the partial film 50a by etching by hydrofluoric acid solution (BHF). Accordingly, bending of the inner wall of the memory hole MH from the Z-direction to the X-Y plane direction is eased at the boundary between the upper array U2m and the insulation film 60. Therefore, it becomes easy to embed the memory film 220 and the semiconductor body 210 in the memory hole MH, so that bending of the semiconductor body 210 in the joint portion JT is eased. Accordingly, satisfactory coverage of the semiconductor body 210 is obtained in the joint portion JT, and the semiconductor body 210 can be prevented from being cut.

While certain embodiments have been described, these embodiments have been presented by way of example only, and are not intended to limit the scope of the inventions. Indeed, the novel methods and configurations described herein may be embodied in a variety of other forms; furthermore, various omissions, substitutions and changes in the form of the methods and configurations described herein may be made without departing from the spirit of the inventions. The accompanying claims and their equivalents are intended to cover such forms or modifications as would fall within the scope and spirit of the inventions.

1. A semiconductor storage device comprising:
a first stack including a plurality of first electrode films stacked in a first direction and electrically isolated from each other;
a second stack provided above the first stack and including a plurality of second electrode films stacked in the first direction and electrically isolated from each other;
an intermediate film provided between the first stack and the second stack; and
a column portion including a semiconductor layer provided to extend in the first direction in the first and second stacks and in the intermediate film, and forming memory cells at an intersection of the semiconductor layer and at least one of the first electrode films and at an intersection of the semiconductor layer and at least one of the second electrode films, wherein
the intermediate film includes a silicon oxide film containing nitrogen.

2. The device of claim 1, further comprising:
a first insulation film provided between the first electrode films; and
a second insulation film provided between the second electrode films, wherein
a nitrogen concentration of the intermediate film is higher than nitrogen concentrations of the first and second insulation films.

3. The device of claim 2, further comprising a third insulation film including a silicon oxide film provided between the intermediate film and the first stack, wherein
the nitrogen concentration of the intermediate film is higher than a nitrogen concentration of the third insulation film.

4. The device of claim 3, wherein the third insulation film is thicker than the first and second insulation films.

5. The device of claim 3, wherein
the third insulation film includes a portion recessed in a direction away from the column portion that extends in the third insulation film, and
the intermediate film protrudes more than the portion of the third insulation film toward the column portion.

6. The device of claim 5, wherein a portion of the third insulation film on a side closer to the second stack in the first direction is recessed relative to the first and second stacks.

7. The device of claim 3, wherein a carbon concentration of the intermediate film is higher than a carbon concentration of the third insulation film.

8. The device of claim 1, wherein the intermediate film includes a first partial film including a silicon oxide film containing nitrogen and a second partial film provided on the first partial film and including a silicon oxide film having a lower nitrogen concentration than the first partial film.

9. The device of claim 8, wherein a carbon concentration of the first partial film is higher than a carbon concentration of the second partial film.

10. The device of claim 3, wherein
the intermediate film includes a first partial film including a silicon oxide film containing nitrogen and a second partial film provided on the first partial film and including a silicon oxide film having a lower nitrogen concentration than the first partial film,
the third insulation film includes a portion recessed in a direction away from the column portion that extends in the third insulation film, and
the first partial film and the second partial film protrude more than the portion of the third insulation film toward the column portion.

11. The device of claim 10, wherein a carbon concentration of the first partial film is higher than a carbon concentration of the second partial film.

12. A manufacturing method of a semiconductor storage device, comprising:
forming a first stack including a plurality of first sacrifice layers stacked in a first direction and isolated from each other;
forming a first hole penetrating through the first stack in the first direction;
forming an intermediate film above the first stack with the first hole formed therein, the intermediate film including a silicon oxide film containing nitrogen;
forming a second stack on the intermediate film, the second stack including a plurality of second sacrifice layers stacked in the first direction and isolated from each other;
forming a second hole penetrating through the second stack and the intermediate film in the first direction and corresponding to the first hole; and
forming a semiconductor layer via a charge storage film on inner walls of the first and second holes to form a column portion in the first and second holes.

13. The method of claim 12, wherein
the first stack is a stack of the first sacrifice layers and first insulation films,
the second stack is a stack of the second sacrifice layers and second insulation films, and
a nitrogen concentration of the intermediate film is higher than nitrogen concentrations of the first and second insulation films.

14. The method of claim 12, wherein the forming of the intermediate film includes
forming a silicon nitride film above the first stack, and
oxidizing the silicon nitride film to form the silicon oxide film containing nitrogen.

15. The method of claim 12, further comprising forming a third insulation film including a silicon oxide film on the first stack, prior to the forming of the first hole, wherein
in the forming of the first hole, the first hole penetrates through the third insulation film on the first stack, and
in the forming of the intermediate film, a silicon oxide film is formed on the third insulation film, the silicon oxide film having a higher nitrogen concentration than the third insulation film.

16. The method of claim 15, wherein, in the forming of the first hole, an upper portion of the third insulation film is recessed in a direction crossing the first direction relative to an inner wall of the first stack.

17. The method of claim 15, wherein a carbon concentration of the intermediate film is higher than a carbon concentration of the third insulation film.

18. The method of claim 12, wherein the forming of the intermediate film includes
forming a first partial film above the first stack, the first partial film including a silicon oxide film containing nitrogen, and
forming a second partial film on the first partial film, the second partial film including a silicon oxide film having a lower nitrogen concentration than the first partial film.

19. The method of claim 18, wherein a carbon concentration of the first partial film is higher than a carbon concentration of the second partial film.

20. The method of claim 12, further comprising, prior to the forming of the intermediate film, filling a sacrifice film containing carbon in the first hole.
